(19) United States
(12) Patent Application Publication
(10) Pub. No.: US 2015/0168480 A1
(43) Pub. Date: Jun. 18, 2015

(54) DEVICE FOR CONTINUOUS DETECTION OF A BREAK IN ELECTRIC INSULATION OF A HIGH-VOLTAGE CABLE AND ASSOCIATED DETECTION METHOD

(71) Applicants: CONTINENTAL AUTOMOTIVE FRANCE, Toulouse (FR); CONTINENTAL AUTOMOTIVE GmbH, Toulouse (FR)

(72) Inventors: Cyril ROBIN, VILLENEUVE TOLOSANE (FR); Eric SERVEL, ROQUES SUR GARONNE (FR)

(21) Appl. No.: 14/559,971

(22) Filed: Dec. 4, 2014

(30) Foreign Application Priority Data
Dec. 16, 2013 (FR) 1362669

(51) Int. Cl. G01R 31/12

(52) U.S. Cl. CPC G01R 31/1272

(57) ABSTRACT

The object of the present invention is a device (D) for continuous detection of a break in electric insulation between a high-voltage cable (10a, 10b) and an electrical ground (C), the high-voltage cable being connected, on one side, to a direct high-voltage current generator (10) and, on the other side, to a device (20) for using said high voltage, and generating a parasitic capacitance Cp with the electrical ground. According to the invention, said detection device (D) comprises:
at least one electrode (40a, 40b) located at a distance (e, d) from the high-voltage cable, forming an additional capacitance Ca with said high-voltage cable and being electrically connected to,
means (30) for measuring a measured capacitance Cm, between said electrode and the electrical ground (C), which means are connected to
means (50) for comparing the value of this measured capacitance and a pre-stored threshold value (Cth), which means are connected to
means (70) for generating a warning message if the value of the measured capacitance is greater than the threshold value, signifying the break in electric insulation of said high-voltage cable,
the value of the measured capacitance being equal to:

$$Cm = \frac{Ca \times Cp}{Ca + Cp}$$

### BACKGROUND OF THE INVENTION

1. Field of the Invention

The invention relates to a device for continuous detection of a break in electric insulation of a high-voltage cable and an associated detection method. Break in electric insulation is taken to mean the connection to the electrical ground of the high-voltage cable.

2. Description of the Related Art

The invention relates more particularly to the electric or hybrid motor vehicles comprising a high-voltage direct current source, for example an 80 V electric battery. For such high direct voltages, the battery is not connected to the electrical ground of the vehicle, i.e. to the chassis thereof, as is the case normally for 12 V direct low-voltage batteries. The battery and the two high-voltage cables, one for the positive pole and one for the negative pole, connecting it electrically to the rest of the electric/hybrid system on board the vehicle, are kept electrically insulated from the electrical ground of the vehicle, i.e. from the chassis of the vehicle, for electrical safety reasons.

The phenomenon of a break in electric insulation can have serious consequences for the user of the vehicle. Indeed, if at least one of the direct high-voltage cables is not insulated from the electrical ground (i.e. from the chassis), the driver or the operator, during vehicle maintenance operations, can enter into contact both with the chassis (by means of the hand thereof placed on the vehicle body for example) and with the high-voltage cable. The latter then runs the risk of being seriously injured, given the high values of direct voltage that are used. Moreover, the connection to the electrical ground (by means of the vehicle chassis) of one of the high-voltage cables can increase the likelihood of a fire starting in the vehicle.

It will be understood that it is, therefore, necessary to constantly check the electric insulation of these two high-voltage cables coming from the battery. This requirement is detailed in the SAE International™ (Society of Automotive Engineers) standard J2344 “Guidelines for Electric Vehicle Safety” of March 2010.

One of the solutions of the prior art consists in measuring the voltage at the terminals of a resistor connected, on one side, to the high-voltage cable, the electric insulation of which is to be checked, and, on the other side, to the chassis of the vehicle.

However, to carry out this measurement, it is necessary to electrically connect the high-voltage cable to the chassis and, therefore, potentially jeopardize the electric insulation of said cable. Therefore, this measurement should preferably be carried out intermittently, for example at a fixed frequency using a switch placed between the resistor and the chassis. Nevertheless, there still remains a risk of a break in electric insulation of the high-voltage cable occurring between two successive measurements.

### SUMMARY OF THE INVENTION

To this end, the invention proposes a device for detecting a break in electric insulation of the high-voltage cable allowing the electric insulation of said cable to be checked continuously and non-intrusively, while not jeopardizing the electric insulation of said cable.

The invention proposes a device for continuous detection of a break in electric insulation between a high-voltage cable and an electrical ground, the high-voltage cable being connected, on one side, to a direct high-voltage current generator and, on the other side, to a device for using said direct high voltage, and generating a parasitic capacitance with the electrical ground. According to the invention, said detection device comprises:
at least one electrode located at a distance from the high-voltage cable, forming an additional capacitance with said high-voltage cable,
means for measuring a measured capacitance, between said electrode and the electrical ground,
means for comparing the value of the measured capacitance and a pre-stored threshold value,
means for generating a warning message if the value of the measured capacitance is greater than the threshold value, signifying the break in electric insulation of said high-voltage cable,
the value of the measured capacitance being equal to:

$$Cm = \frac{Ca \times Cp}{Ca + Cp}$$

where:

Cm=measured capacitance (pF)

Ca=additional capacitance (pF)

Cp=parasitic capacitance (pF)

Therefore, sensibly, the parasitic capacitance Cp is measured indirectly and continuously via the addition of an electrode positioned such that it creates an additional capacitance Ca with the high-voltage cable. Given that the additional capacitance Ca has a fixed and known value, by measuring the capacitance Cm at the terminals of this electrode, the parasitic capacitance Cp between the high-voltage cable and the electrical ground is measured indirectly. Any variation in the measured capacitance Cm represents a variation in the parasitic capacitance Cp. If the parasitic capacitance Cp, and therefore the measured capacitance Cm exceeds a threshold, then a break in the electric insulation of said cable is detected.

In a second embodiment, the continuous detection device further comprises:
a reference electrode located at a distance from the high-voltage cable, forming a reference capacitance with said high-voltage cable and connected to the electrical ground,
the value of the measured capacitance being equal to:

$${Cm}^{′} - \frac{Ca \times Ceq}{Ca + Ceq}$$

where:

Ceq=Cref+Cp

Cm′=measured capacitance (pF)

Ceq=equivalent capacitance (pF)

Cref=reference capacitance (pF)

Ca=additional capacitance (pF).

Preferably, the additional capacitance is at least ten times greater than the parasitic capacitance or, according to the second embodiment, the reference capacitance is at least ten times greater than the parasitic capacitance, and the additional capacitance is at least twice as great as the reference capacitance.

The electrode can consist of a planar electrode located opposite the high-voltage cable or a cylindrical electrode made from conductive material surrounding the high-voltage cable.

Similarly, the reference electrode can consist of a planar electrode located opposite the high-voltage cable or of a cylindrical electrode made from conductive material surrounding the high-voltage cable.

The means of generating a warning message are preferably visual or sound means signaling the break in electric insulation.

The invention also relates to a method for continuous detection of a break in electric insulation between a high-voltage cable and an electrical ground using the continuous detection device according to the features listed above, said detection method comprising the following steps:
Step a: the comparing means storing a threshold value of the measured capacitance,
Step b: the measuring means measuring the measured capacitance and
Step c: the comparing means comparing the value of the measured capacitance and the pre-stored threshold value,
Step d: if the value of the measured capacitance is greater than the threshold value, then a warning message is generated by the means for generating a warning message,

otherwise,
Step e: if the value of the measured capacitance is less than the threshold value, then steps b, c, d are repeated.

In the first embodiment, the method further comprises a prior stage for determining a maximum value of the parasitic capacitance and, during step a, the threshold value is equal to the maximum value of the parasitic capacitance.

In the second embodiment, the threshold value is equal to:

Cth′=A×Cref

where:

Cth′=threshold value

Cref=the value of the reference capacitance (pF) and

A=safety factor

The invention also relates to any motor vehicle comprising the continuous detection device according to any one of the features listed above.

### BRIEF DESCRIPTION OF THE DRAWINGS

Other objects, features and advantages of the invention will emerge upon reading the following description given by way of nonlimiting example and upon examining the appended drawings wherein:

FIG. 1 schematically shows a first embodiment of the detection device D according to the invention,

FIG. 2a schematically shows in detail the planar electrode 40a according to a first alternative of the first embodiment of the detection device D,

FIG. 2b schematically shows in detail the cylindrical electrode 40b according to a second alternative of the first embodiment of the detection device D,

FIG. 3 schematically shows a second embodiment of the detection device D′ according to the invention,

FIG. 4a schematically shows in detail the planar electrode 40a and the planar reference electrode 41a according to a first alternative of the second embodiment of the detection device D′,

FIG. 4b schematically shows in detail the cylindrical electrode 40b and the cylindrical reference electrode 41b according to a second alternative of the second embodiment of the detection device D′.

### DETAILED DESCRIPTION OF THE PREFERRED EMBODIMENT

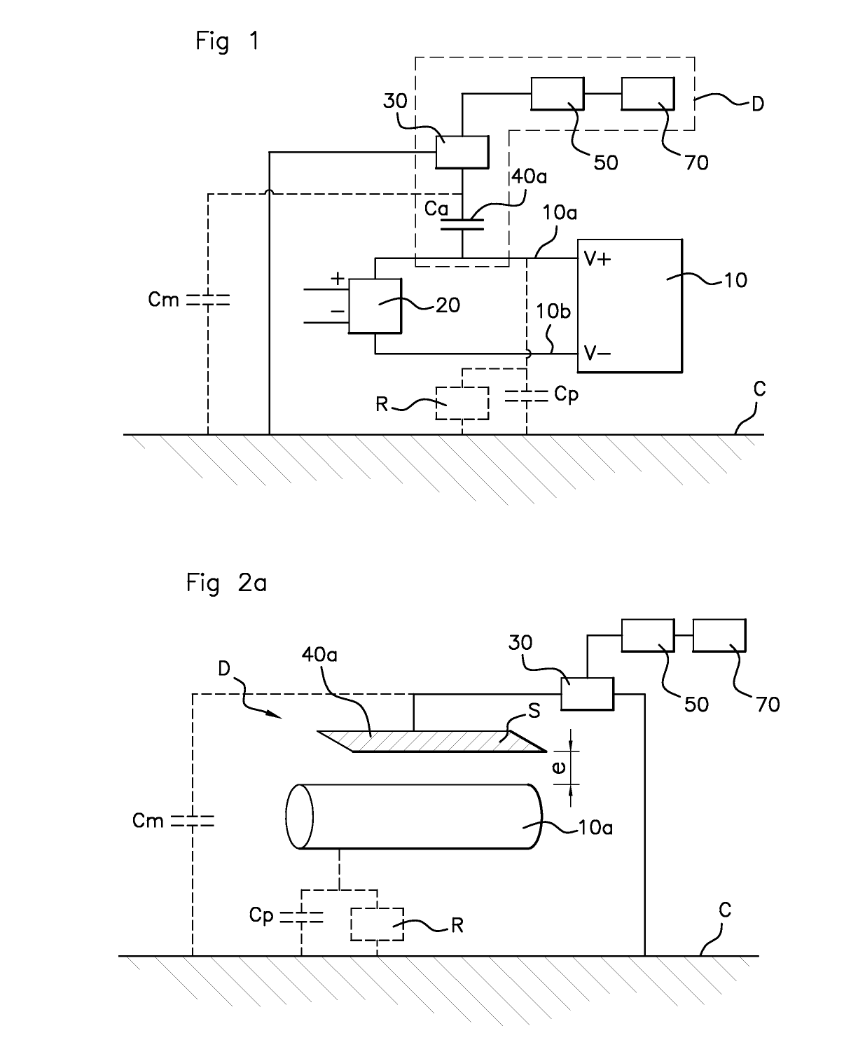

A first embodiment of the continuous detection device D according to the invention is shown in FIG. 1. A high-voltage battery-type direct high-voltage generator 10 has the two terminals, positive (V+) and negative (V−), thereof electrically connected by two high-voltage cables 10a and 10b to a device 20 for using said direct voltage, for example to a low-voltage DC-to-DC converter. The usage device 20 is electrically connected to the onboard electrical or electronic system of the vehicle (not shown). The assembly is loaded within said vehicle.

The direct high-voltage circuit is made up of the battery 10 and of the two high-voltage cables 10a, 10b and is insulated from the chassis C of the vehicle which is connected to the electrical ground.

The proximity between two high-voltage cables 10a, 10b (which are not connected to the electrical ground) and the chassis C of the vehicle (which is connected to the electrical ground) creates a resistance R of infinite value between each of said high-voltage cables 10a, 10b and the chassis C of the vehicle. In FIG. 1, for reasons of clarity, only the resistance R between the high-voltage cable 10a connected to the positive terminal (V+) of the high-voltage battery 10 and the chassis C of the vehicle is shown. Moreover, this resistance R of infinite value is accompanied in parallel by a parasitic capacitance Cp of low value (a few pF) between each of the high-voltage cables 10a, 10b and the chassis C. This parasitic capacitance Cp is due, amongst others, to the difference in potential between each of the high-voltage cables 10a, 10b and the chassis C.

If, for example, the high-voltage cable 10a connected to the positive terminal (V+) of the high-voltage battery 10 is no longer electrically insulated and becomes electrically connected to the chassis C, the resistance R between the two will drop considerably to take a value equal to the resistance of the connection between the high-voltage cable 10a and the chassis C of the vehicle. The parasitic capacitance Cp is shorted by this low value resistance.

The invention proposes continuously measuring the value of the parasitic capacitance Cp between at least one of the high-voltage cables 10a, 10b and the chassis C (i.e. the electrical ground of the vehicle) in order to detect any break in electric insulation of said high-voltage cable 10a, 10b.

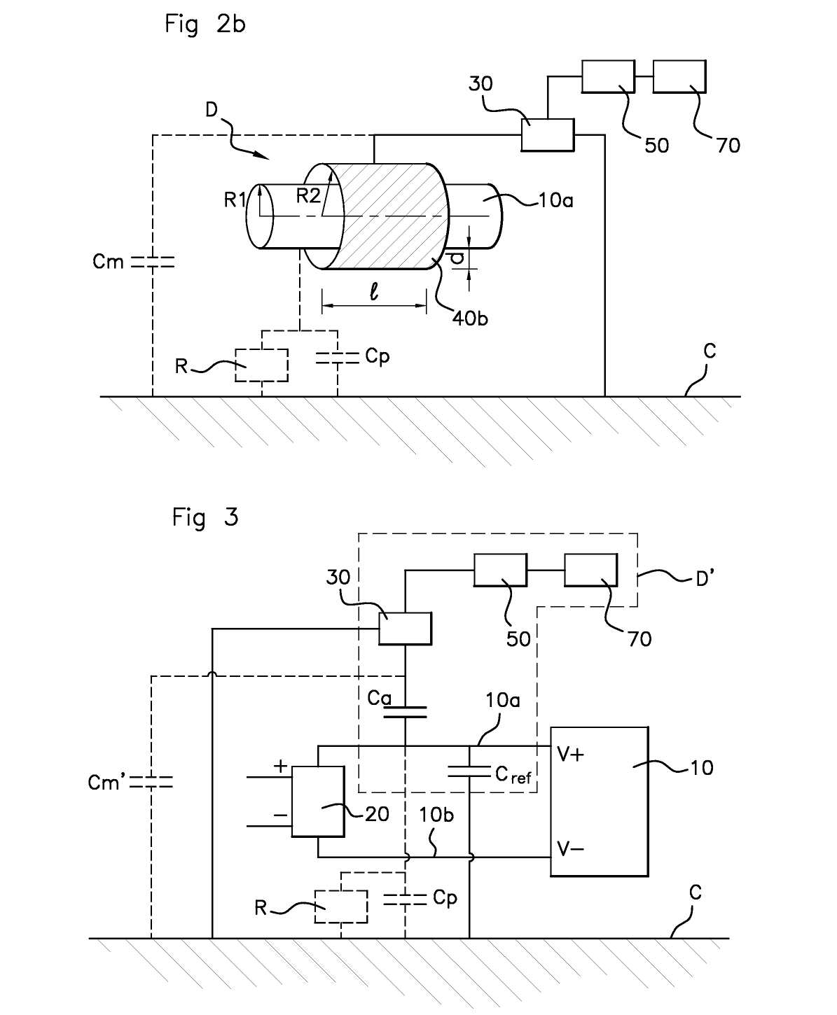

To this end, the invention proposes adding an electrode 40a (cf. FIG. 2a) proximate to the high-voltage cable 10a, the electric insulation of which is to be checked, as well as measuring means 30, connected to the chassis C (electrical ground) and measuring a measured capacitance Cm existing between said electrode 40a and the chassis C. The presence of the electrode 40a proximate to the high-voltage cable 10a creates an additional capacitance Ca between the electrode 40a and said cable. The additional capacitance Ca is, indeed, made up of two electrodes, the electrode 40a and the electrode formed by the cable.

Given the presence of the parasitic capacitance Cp between the high-voltage cable 10a and the chassis C, the measuring means 30 not only measure the value of the additional capacitance Ca but measure a measured capacitance Cm equivalent to the two capacitances mounted in series, namely the additional capacitance Ca and the parasitic capacitance Cp (cf. FIG. 1).

The measured capacitance Cm is therefore equivalent to:

$$Cm = \frac{Ca \times Cp}{Ca + Cp} \qquad [ equation 1 ]$$

Since the value of the additional capacitance Ca is fixed and known, the variation in the value of the measured capacitance Cm therefore represents the variation in the value of the parasitic capacitance Cp.

Indeed, according to the equation 1, any variation in the value of the parasitic capacitance Cp produces a variation in the value of the measured capacitance Cm.

The continuous detection device D according to the invention therefore allows the value of the parasitic capacitance Cp to be measured indirectly by measuring the measured capacitance Cm.

By sensibly choosing the value of the additional capacitance Ca to be much greater than the value of the parasitic capacitance Cp, for example at least ten times greater than that of the parasitic capacitance Cp, the equation[1] gives:

Cm≈Cp

As a result, the value of the measured capacitance Cm, when the high-voltage cable 10a is insulated from the chassis C (i.e. the electrical ground), is therefore substantially equal to the value of the parasitic capacitance Cp.

During a break in electric insulation of the high-voltage cable 10a, i.e. when the latter is connected to the electrical ground of the chassis C, the parasitic capacitance Cp disappears since it is shorted by the resistance R of the high-voltage cable 10a connecting to the chassis C. In this case, there is only one capacitance between the high-voltage cable 10a, which is equal to the additional capacitance Ca.

When the parasitic capacitance Cp is shorted, then:

Cm≅Ca

Of course, there can be several intermediate cases of a break in electric insulation, depending on the strength of the leakage current between the high-voltage cable 10a and the chassis C. The value of the measured capacitance Cm, therefore, varies from the value of the parasitic capacitance Cp (no break in electric insulation) to a maximum value equal to the value of the additional capacitance Ca (in the case of a break in electric insulation).

In order to detect all of the cases of a break in electric insulation, the invention proposes a prior step of measuring a maximum value of the parasitic capacitance Cpmax.

This prior step is carried out on several vehicles. For example, a capacitance meter is electrically connected between the high-voltage cable 10a and the chassis C of the vehicle, then the value which is equal to the value of the parasitic capacitance Cp is measured (in the case where there is no break in electric insulation of said cable). This is repeated for each vehicle. The maximum value Cpmax of the values of parasitic capacitances measured in this manner allows a threshold value Cth of the measured capacitance Cm to be defined and therefore:

Cth≈Cpmax

Exceeding this threshold Cth then signifies the break in electric insulation between the high-voltage cable 10a and the electrical ground, i.e. the chassis C.

In order to distinguish between these two cases (break in electric insulation or not), it is recommended to calculate the value of the additional capacitance Ca to be much greater than the value of the maximum parasitic capacitance Cpmax.

For example:

Ca=10×Cpmax

Therefore, the value of the measured capacitance Cm varies between the value of the maximum parasitic capacitance Cpmax and ten times the value of said maximum parasitic capacitance (since Ca=10×Cpmax), which allows rapid detection of a case of a break in electric insulation.

The measuring means 30, measuring the variation in the measured capacitance Cm, are known to a person skilled in the art, and consist, for example, of a device for measuring the variation in a charge transfer capacitance, or any equivalent device, such as described in the patent FR 2 938 344 B1, for example.

Comparing means 50, connected to the measuring means 30, then compare the value of the measured capacitance Cm with the threshold value Cth which has been previously stored in the comparing means 50. The comparing means 50 are, for example, software means incorporated in a microprocessor.

If the value of the measured capacitance Cm is greater than the threshold value Cth, then generating means 70 trigger a warning message, for example a visual or sound warning message (for the user/driver of the vehicle) signifying the break in electric insulation of the high-voltage cable 10a, i.e. indirectly the break in electric insulation of the high-voltage battery 10 of the vehicle.

The additional capacitance Ca is made up of two electrodes:
a first electrode, for example a planar electrode 40a (cf. FIG. 2a) made of conductive material, located at a distance e from the high-voltage cable 10a, and positioned opposite thereto, for example a copper sheet of a few square centimeters of surface S, and
a second electrode made up by said cable 10a itself.

This planar electrode 40a is not connected to the high-voltage cable 10a (or 10b), and is electrically connected to the means 30 for measuring the measured capacitance Cm, between said electrode 40a and the chassis C.

In the case of a planar electrode 40a, made up of a copper sheet located at a distance e=1 mm from the cable, the surface S of the copper sheet is equal to:

$$S = \frac{Ca \times 3}{{ɛ}_{o} \times {ɛ}_{r}}$$

where:

∈o=the permittivity of free space equal to

$$\frac{1}{36 \times π \times {10}^{9}} ,$$

∈r=the dielectric constant of the insulator surrounding the cable 10a, for example equal to 3 for a plastic,

Ca=additional capacitance.

For a maximum value of the parasitic capacitance Cpmax equal to 1 pF, if the aim is to have an additional capacitance Ca equal to 10 pF (in the case where Ca=10×Cpmax), then the surface S must be equal to 4 cm².

A copper sheet of 4 cm² is, therefore, sufficient to create an additional capacitance Ca of approximately 10 pF.

The electrode can also take the form of a cylindrical electrode 40b, in the shape of a copper ring partially or totally surrounding the insulating sheath of the high-voltage cable 10a (cf. FIG. 2b).

In this case, the length l of the cylindrical electrode 40b is given by the formula:

$$1 = \frac{Ca \times ln \frac{R 2}{R 1}}{2 \times π \times {ɛ}_{o} \times {ɛ}_{r}}$$

where:

R1=radius of the high-voltage cable,

R2=internal radius of the cylindrical electrode 40b,

$$\frac{1}{36 \times π \times {10}^{9}} ,$$

∈o=the permittivity of free space equal to

∈r=the dielectric constant of the insulator surrounding the cable 10a, for example equal to 3 for a plastic,

Π=3.14

Ca=additional capacitance.

For example, if:

R1=0.015 m

R2=0.016 m

then d=R2−R1=0.001 m

If the aim is to obtain an additional capacitance Ca=10 pF, then the length of the cylindrical electrode is equal to:

l=0.010 m

It is important to position the planar electrode 40a, or the cylindrical electrode 40b, at a certain distance (e, d) from the high-voltage cable 10a in order to insulate the electrode from potential discharges coming from the high-voltage cable 10a, which can occur during overvoltage in said cable. These discharges could damage the electrode 40a, 40b. For example, the distance e between the planar electrode 40a and the insulating sheath of the high-voltage cable 10a or between the internal radius R2 of the cylindrical electrode 40b and the radius R1 of the high-voltage cable 10a, namely d=R2−R1, is preferably in the region of 1 mm.

As indicated above, the value of the parasitic capacitance Cp can vary from one vehicle to another. This can cause cases of non-detection of a break in insulation on some vehicles having a parasitic capacitance Cp less than the maximum value of the parasitic capacitance Cpmax established.

To overcome this disadvantage, the invention proposes a second embodiment of the continuous detection device D′ shown in FIG. 3.

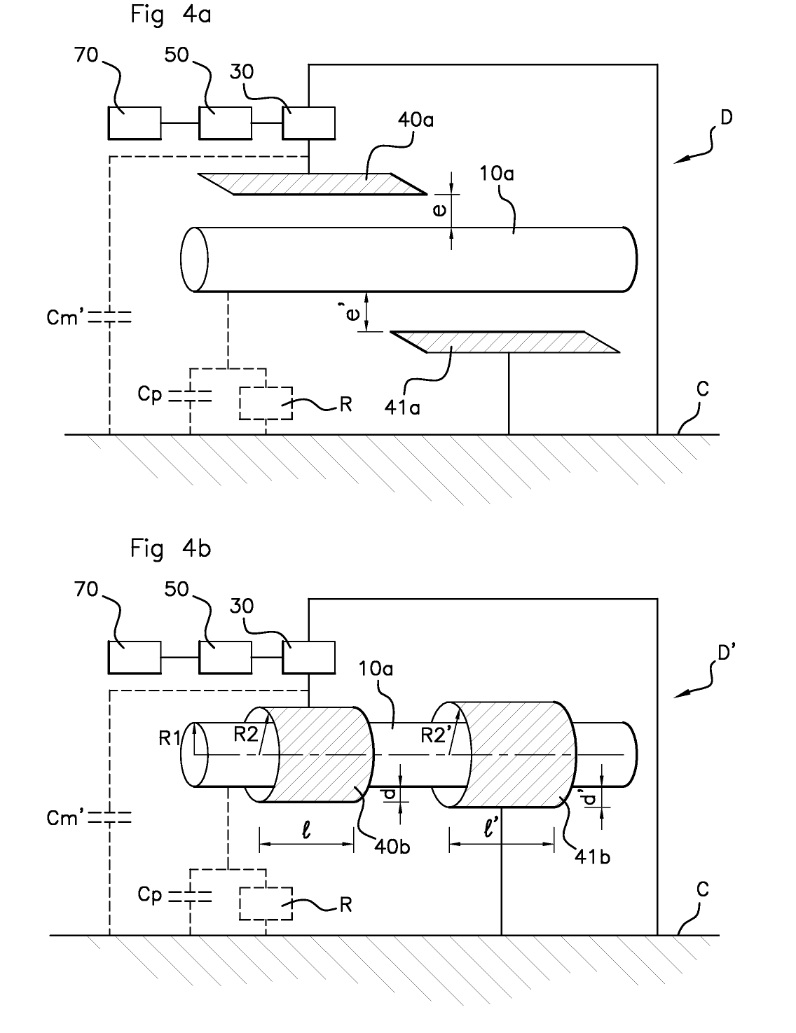

In this second embodiment, the continuous detection device D′ further comprises a reference electrode 41a, 41b, located at a distance e′, d′ (cf. FIGS. 4a, 4b) from the high-voltage cable 10a and electrically connected to the chassis C of the vehicle. This reference electrode can, like the electrode 40a, 40b, be a planar reference electrode 41a (positioned opposite the high-voltage cable), or a cylindrical reference electrode 41b (surrounding the high-voltage cable). This reference electrode (41a, 41b) creates a reference capacitance Cref between the high-voltage cable 10a and the chassis C.

The planar reference electrode 41a is located at a distance e′ from the sheath of the high-voltage cable 10a. Preferably e′=1 mm.

The cylindrical electrode 41b has an internal radius R2′, such that the distance d′ between the internal radius R2′ of said electrode and the radius R1 of the high-voltage cable 10a, namely d′=R2′−R1, is preferably in the region of 1 mm.

Likewise, the surface S′ of the planar reference electrode 41a is given by:

$${S}^{′} = \frac{Cref \times {e}^{′}}{{ɛ}_{o} \times {ɛ}_{r}}$$

where:

∈o=the permittivity of free space equal to

$$\frac{1}{36 \times π \times {10}^{9}} ,$$

∈r=the dielectric constant of the insulator surrounding the cable 10a, for example equal to 3 for a plastic,

e′=distance between the planar electrode 41a and the insulating sheath of the high-voltage cable 10a,

Cref=reference capacitance (pF).

In the case of a cylindrical reference electrode 41b, the length l′ of said electrode 41b is given by:

$${1}^{′} = \frac{Cref \times ln \frac{R {2}^{′}}{R 1}}{2 \times π \times {ɛ}_{o} \times {ɛ}_{r}}$$

R1=radius of the high-voltage cable,

R2′=internal radius of the cylindrical electrode 41b,

∈o=the permittivity of free space equal to

$$\frac{1}{36 \times π \times {10}^{9}} ,$$

∈r=the dielectric constant of the insulator surrounding the cable 10a, for example equal to 3 for a plastic,

Cref=reference capacitance,

Π=3.14.

In this second embodiment, the parasitic capacitance Cp and the reference capacitance Cref, which are both connected to the cable and to ground, are mounted in parallel. As a result, an equivalent capacitance Ceq is defined by:

Ceq=Cref+Cp

By sensibly choosing the reference capacitance Cref with a value that is clearly greater than the parasitic capacitance Cp, for example at least ten times greater than the parasitic capacitance Cp, then the value of the parasitic capacitance Cp can be disregarded with respect to the value of the reference capacitance Cref and:

Ceq=Cref

Therefore, the measured capacitance Cm′ is equal to:

$${Cm}^{′} = \frac{Ca \times Ceq}{Ca + Ceq}$$

and the value of the measured capacitance Cm′ becomes:

$${Cm}^{′} = \frac{Ca \times Cref}{Ca + Cref}$$

The value of the reference capacitance Cref is sensibly chosen to be clearly less than the value of the additional capacitance Ca, for example at least two times less. Therefore, in this second embodiment of the invention, preferably:

Ca>>Cref>>Cp

For example, Cp=1 pF, Cref=10 pF and Ca=50 pF.

The reference capacitance Cref is at least ten times greater than the parasitic capacitance Cp, and the additional capacitance Ca is at least twice as great as the reference capacitance Cref.

Therefore, when there is no break in electric insulation of the high-voltage cable 10a, then:

Cm′=Ceq≅Cref

As a result, the threshold value of the capacitance Cth′ is equal to the value of the reference capacitance Cref.

The threshold value of the capacitance is defined as:

Cth′=A×Cref

where:

A=safety factor, and the value of A is, for example between 1 and 2.

If the value of the measured capacitance Cm′ is greater than the threshold value Cth′, namely Cm′>Cth′, then there is a break in electric insulation of the high-voltage cable 10a.

The invention also relates to a method for continuous detection of a break in electric insulation between a high-voltage cable 10a and the electrical ground, in this example, the chassis C of the vehicle, comprising the following steps:
Step a: storing, in the comparing means 50, a threshold value Cth, Cth′ of the measured capacitance Cm, Cm′,
Step b: the measuring means 30 measuring the measured capacitance Cm, Cm′,
Step c: the comparing means 50 comparing the value of the measured capacitance Cm, Cm′ and the threshold value Cth, Cth′,
Step d: if the value of the measured capacitance Cm, Cm′ is greater than the threshold value Cth, Cth′, the generating means 70 trigger a warning message, otherwise,
Step e: if the value of the measured capacitance Cm, Cm′ is less than the threshold value Cth, Cth′, then steps b, c, d are repeated.

In a first embodiment of the invention, the detection method further comprises a prior stage for determining a maximum parasitic capacitance Cpmax, and during step a, Cth=Cpmax.

In a second embodiment of the invention, a reference electrode 41a, 41b is located at a distance (e′, d′) from the high-voltage cable 10a and is connected to the electrical ground, creating a reference capacitance Cref, the value of which is fixed and known, and, during step a:

Cth′−A×Cref

where:

A=safety factor, and the value of A is, for example, between 1 and 2.

Therefore, the invention allows the break in electric insulation of a high-voltage cable connected to a direct high-voltage generator to be sensibly detected in a non-intrusive manner by using the continuous measurement of the parasitic capacitance existing between said cable and the electrical ground.

Of course, the invention is not limited to the embodiments described and can be produced by any equivalent means.

For example, the additional capacitance and/or the reference capacitance can be produced using capacitors or by any other means known to a person skilled in the art.

1. A device (D) for continuous detection of a break in electric insulation between a high-voltage cable (10a, 10b) and an electrical ground (C), the high-voltage cable (10a, 10b) being connected, on one side, to a high-voltage direct current generator (10) and, on the other side, to a device (20) for using said high voltage, and generating a parasitic capacitance (Cp) with the electrical ground (C), said detection device (D) comprising:
at least one electrode (40a, 40b) located at a distance (e, d) from the high-voltage cable (10a, 10b), forming an additional capacitance (Ca) with said high-voltage cable (10a, 10b),
means (30) for measuring a measured capacitance (Cm), between said electrode (40a, 40b) and the electrical ground (C),
means (50) for comparing the value of the measured capacitance (Cm) and a pre-stored threshold value (Cth),
means (70) for generating a warning message if the value of the measured capacitance (Cm) is greater than the threshold value (Cth), signifying the break in electric insulation of said high-voltage cable (10a, 10b),
the value of the measured capacitance (Cm) being equal to:
$$Cm = \frac{Ca \times Cp}{Ca + Cp}$$
where:
Cm=measured capacitance
Ca=additional capacitance
Cp=parasitic capacitance.

2. The detection device (D′) as claimed in claim 1, further comprising:
a reference electrode (41a, 41b) located at a distance (e′, d′) from the high-voltage cable (10a, 10b), forming a reference capacitance (Cref) with said high-voltage cable (10a, 10b) and connected to the electrical ground (C),
the value of the measured capacitance (Cm′) being equal to:
$${Cm}^{′} = \frac{Ca \times Ceq}{Ca + Ceq}$$
where:
Cm′=measured capacitance
Ceq=equivalent capacitance equal to:
Ceq=Cref+Cp
Cref=reference capacitance
Ca=additional capacitance.

3. The detection device (D, D′) as claimed in claim 1, wherein the additional capacitance (Ca) is at least ten times greater than the parasitic capacitance (Cp).

4. The detection device (D′) as claimed in claim 2, wherein the reference capacitance (Cref) is at least ten times greater than the parasitic capacitance (Cp), and the additional capacitance (Ca) is at least twice as great as the reference capacitance (Cref).

5. The detection device (D, D′) as claimed in claim 1, wherein the electrode (40a, 40b) consists of a planar electrode (40a) located opposite the high-voltage cable (10a, 10b) or a cylindrical electrode (40b) made from conductive material surrounding the high-voltage cable (10a, 10b).

6. The detection device (D′) as claimed in claim 4, wherein the additional capacitance (Ca) is at least ten times greater than the parasitic capacitance (Cp), and the reference electrode (41a, 41b) consists of a planar electrode (41a) located opposite the high-voltage cable (10a, 10b) or of a cylindrical electrode (41b) made from conductive material surrounding the high-voltage cable (10a, 10b).

7. A method for continuous detection of a break in electric insulation between a high-voltage cable (10a, 10b) and an electrical ground (C) using the detection device (D, D′) as claimed in claim 1, which comprises the following steps:
Step a: the comparing means (50) storing a threshold value (Cth, Cth′) of the measured capacitance (Cm, Cm′),
Step b: the measuring means (30) measuring the measured capacitance (Cm, Cm′) and
Step c: the comparing means (50) comparing the value of the measured capacitance (Cm, Cm′) and the pre-stored threshold value (Cth, Cth′),
Step d: if the value of the measured capacitance (Cm, Cm′) is greater than the threshold value (Cth, Cth′), then a warning message is generated by the generating means (70),
otherwise,
Step e: if the value of the measured capacitance (Cm, Cm′) is less than the threshold value (Cth, Cth′), then steps b, c, d are repeated.

8. The continuous detection method as claimed in claim 7, further comprising a prior stage for determining a maximum value of the parasitic capacitance (Cpmax) and, during step a, the threshold value (Cth) is equal to the maximum value of the parasitic capacitance (Cpmax).

9. The continuous detection method as claimed in claim 7, wherein the detection device (D′) further comprises:
a reference electrode (41a, 41b) located at a distance (e′, d′) from the high-voltage cable (10a, 10b), forming a reference capacitance (Cref) with said high-voltage cable (10a, 10b) and connected to the electrical ground (C),
the value of the measured capacitance (Cm′) being equal to:
$${Cm}^{′} = \frac{Ca \times Ceq}{Ca + Ceq}$$
where:
Cm′=measured capacitance
Ceq=equivalent capacitance equal to:
Ceq=Cref+Cp
Cref=reference capacitance
Ca=additional capacitance, and the reference electrode (41a, 41b) consists of a planar electrode (41a) located opposite the high-voltage cable (10a, 10b) or of a cylindrical electrode (41b) made from conductive material surrounding the high-voltage cable (10a, 10b), the threshold value (Cth′) is equal to:
Cth′=A×Cref
where:
Cth′=threshold value
Cref=the value of the reference capacitance and
A=safety factor.

10. A motor vehicle comprising the continuous detection device (D, D′) as claimed in claim 1.
